(19) United States
(12) Patent Application Publication
(10) Pub. No.: US 2007/0092996 A1
(43) Pub. Date: Apr. 26, 2007

(54) METHOD OF MAKING SEMICONDUCTOR PACKAGE WITH REDUCED MOISTURE SENSITIVITY

(75) Inventors: Wai Yew Lo, Petaling Jaya (MY); Pei Chen Ooi, Selangor (MY)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc., Austin, TX (US)

(21) Appl. No.: 11/551,615

(22) Filed: Oct. 20, 2006

(30) Foreign Application Priority Data
Oct. 21, 2005 (MY) PI20054960

(51) Int. Cl. H01L 21/58

(52) U.S. Cl. 438/108; 438/126; 438/113; 438/122

(57) ABSTRACT

A method of making a semiconductor package (10) includes placing an integrated circuit (IC) die (12) on a first side (14) of a substrate (16) and electrically connecting the IC die (12) to the first side (14) of the substrate (16). First solder balls (22) are attached to a second side (24) of the substrate (16). An interposer (28) is attached to the IC die (12). A molding operation is performed to encapsulate the IC die (12), the substrate (16), at least a portion of the interposer (28) and at least a portion of the first solder balls (22).

### BACKGROUND OF THE INVENTION

The present invention relates to the packaging of integrated circuits (ICs) and more particularly to a semiconductor package with reduced moisture sensitivity and a method of making such a semiconductor package.

Most semiconductor packages include BT (bismaleimide triazene) and FR4 (Flame Retardant-Type 4 woven glass reinforced epoxy resin) substrates. Common BT and FR4 substrates are impregnated with solder mask material, which is known to absorb moisture. Thus, semiconductor packages absorb moisture from the ambient environment through diffusion. The moisture absorbed by a semiconductor package vaporises when subjected to heat during processing, creating internal stresses within the semiconductor package. The internal stresses exerted by the vaporised moisture often cause interfacial delamination, and in more severe cases, external package cracks, both of which lead to package failure. Hence, the presence of moisture within a semiconductor package reduces the reliability of the semiconductor package.

In view of the foregoing, it would be desirable to have a semiconductor package with reduced moisture sensitivity and a method of making such a semiconductor package.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged cross-sectional view of a plurality of integrated circuit (IC) dice coupled to a substrate in accordance with an embodiment of the present invention;

FIG. 2 is an enlarged cross-sectional view of solder balls being attached to the substrate of FIG. 1;

FIG. 3 is an enlarged cross-sectional view of an interposer attached to the IC dice of first level semiconductor packages of FIG. 2;

FIG. 4 is an enlarged cross-sectional view of a molding operation performed on the first level semiconductor packages of FIG. 3; and

FIG. 5 is an enlarged cross-sectional view of encapsulated, first level semiconductor packages of FIG. 4 being singulated to form individual second level semiconductor packages; and

FIG. 6 is an enlarged cross-sectional view of one of the second level semiconductor packages of FIG. 5.

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention. In the drawings, like numerals are used to indicate like elements throughout.

The present invention provides a method of making a semiconductor package including the steps of placing an integrated circuit (IC) die on a first side of a substrate and electrically connecting the IC die to the first side of the substrate. A plurality of first solder balls is attached to a second side of the substrate. An interposer is attached to the IC die. A molding operation is performed to encapsulate the IC die, the substrate, at least a portion of the interposer and at least a portion of the first solder balls.

The present invention also provides a method of making a plurality of semiconductor packages including the steps of placing a plurality of integrated circuit (IC) dice on a first side of a substrate and electrically connecting the IC dice to the first side of the substrate. A plurality of first solder balls is attached to a second side of the substrate. An interposer is attached to the IC dice. A molding operation is performed to encapsulate the IC dice, the substrate, at least a portion of the interposer and at least a portion of the first solder balls. A singulating operation is performed to separate adjacent ones of the IC dice, thereby forming the plurality of semiconductor packages.

The present invention further provides a semiconductor package including an integrated circuit (IC) die placed on and electrically connected to a first side of a substrate. A plurality of first solder balls is attached to a second side of the substrate. An interposer is attached to the IC die. A molding compound encapsulates the IC die, the substrate, at least a portion of the interposer and at least a portion of the first solder balls.

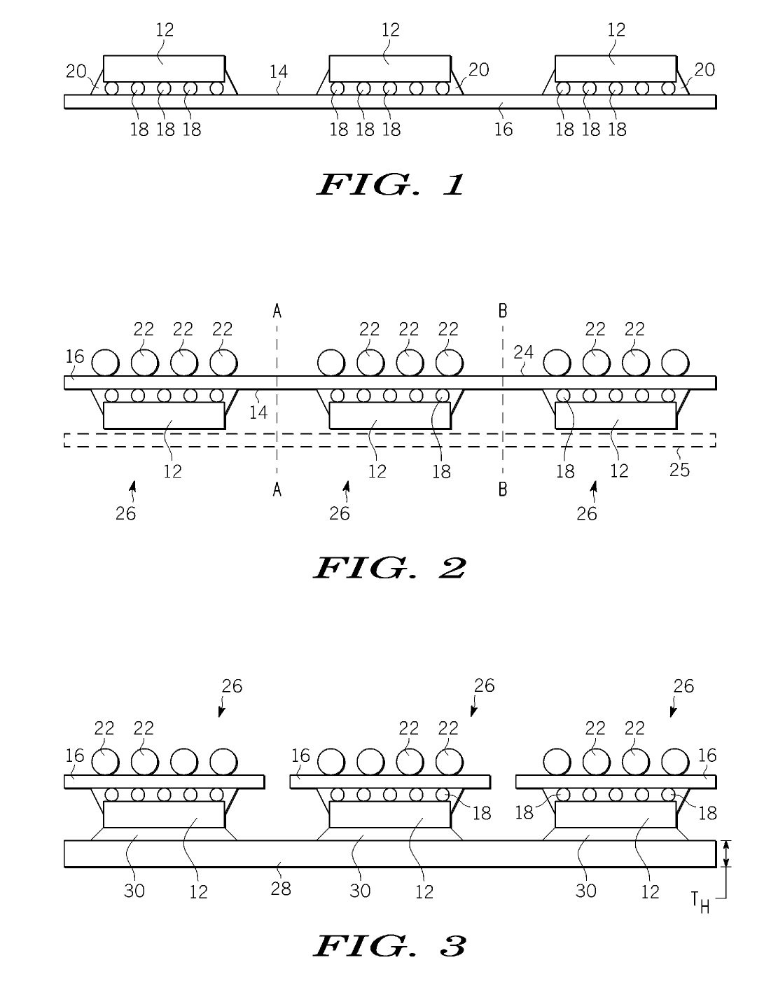

FIGS. 1 through 5 are enlarged cross-sectional views that illustrate a method of making a plurality of semiconductor packages 10 in accordance with an embodiment of the present invention.

Referring now to FIG. 1, a plurality of integrated circuit (IC) dice 12 is placed on and electrically connected to a first side 14 of a substrate 16. The IC dice 12 may be processors, such as digital signal processors (DSPs), special function circuits, such as memory address generators, or circuits that perform any other type of function. The IC dice 12 are not limited to a particular technology such as CMOS, or derived from any particular wafer technology. Further, the present invention can accommodate dice of various sizes, as will be understood by those of skill in the art. A typical example is a memory die having a size of about 15 mm by 15 mm. The substrate 16 may be an FR4 or BT substrate impregnated with solder mask material, as is commonly used in semiconductor packaging. As shown in FIG. 1, the IC dice 12 are electrically connected to the substrate 16 via a plurality of controlled collapse chip connection (C4) type interconnections 18. The C4 type interconnections 18 are formed by placing a plurality of flip chip bumps on one side (front side) of the IC dice 12 against a plurality of corresponding bonding pads on the substrate 16. The flip chip bumps are subjected to heat and/or vibration, as is known in the art, to electrically couple the flip chip bumps on the IC dice 12 to the bonding pads on the substrate 16. After the IC dice 12 are electrically connected to the substrate 16, a reflow operation is preferably performed.

In this particular embodiment, an underfill 20 such as, for example, an epoxy resin that is highly filled with silica particles, as is commonly used in semiconductor packaging, is dispensed into and fills a gap between the respective IC dice 12 and the substrate 16, such that the underfill 20 surrounds the C4 type interconnections 18. The underfill 20 is subsequently cured. However, it should be understood that the present invention is not limited to the underfilling process described or by the composition of the underfill 20. For example, a pre-applied underfill or a no-flow underfill may be used in alternative embodiments. In addition, the dice 20 may be placed within recesses formed in the substrate 16 for receiving the dice 20.

Referring now to FIG. 2, a plurality of first conductive balls 22 is attached to a second side 24 of the substrate 16. As shown in FIG. 2, the IC dice 12 and the substrate 16 are positioned in a “dead bug” orientation for the attachment of the first conductive balls 22. The first conductive balls 22 may be C5 solder balls and attached to the substrate 16 using known solder ball attach processes. In addition, a tape 25 or other disposable or re-usable form may be temporarily attached to the back side of the IC dice 20 during the ball 22 attach process.

FIG. 2 also shows an optional first singulating operation. For example, saw singulation may be performed along the vertical lines A-A and B-B to separate adjacent ones of the IC dice 12, thereby forming a plurality of first level semiconductor packages 26. In this particular example, the first singulating operation is performed after the attachment of the first solder balls 22 to the substrate 16. However, those of skill in the art will understand that the first singulating operation can also be performed before the attachment of the first solder balls 22 to the substrate 16 or not performed at all.

Referring now to FIG. 3, an interposer 28 is attached to the IC dice 12 of the first level semiconductor packages 26. More particularly, the interposer 28 is attached to an opposite side (back side) of the IC dice 12 from the C4 type interconnections 18. If the tape 25 (FIG. 2) was used, then such tape is removed prior to attachment of the interposer 28. The interposer 28 protects the backside of the IC dice 12 from external mechanical stresses and thereby prevents the backside of the IC dice 12 from cracking. In this particular embodiment, the interposer 28 is a heat sink with a thickness T_{H} of about 0.3 millimetres (mm). The interposer 28 conducts away and disperses the heat generated by the IC dice 12. Nevertheless, it should be understood that the present invention is not limited to the described function or thickness of the interposer 28. The interposer 28 may be made of copper or some other conductive material, as is known by those of skill in the art. An epoxy 30 is used to attach the interposer 28 to the IC dice 12. The epoxy 30 may be a conductive epoxy, a non-conductive epoxy or a film epoxy. In a preferred embodiment of the invention, the epoxy 30 is a silver (Ag) filled conductive die attach epoxy.

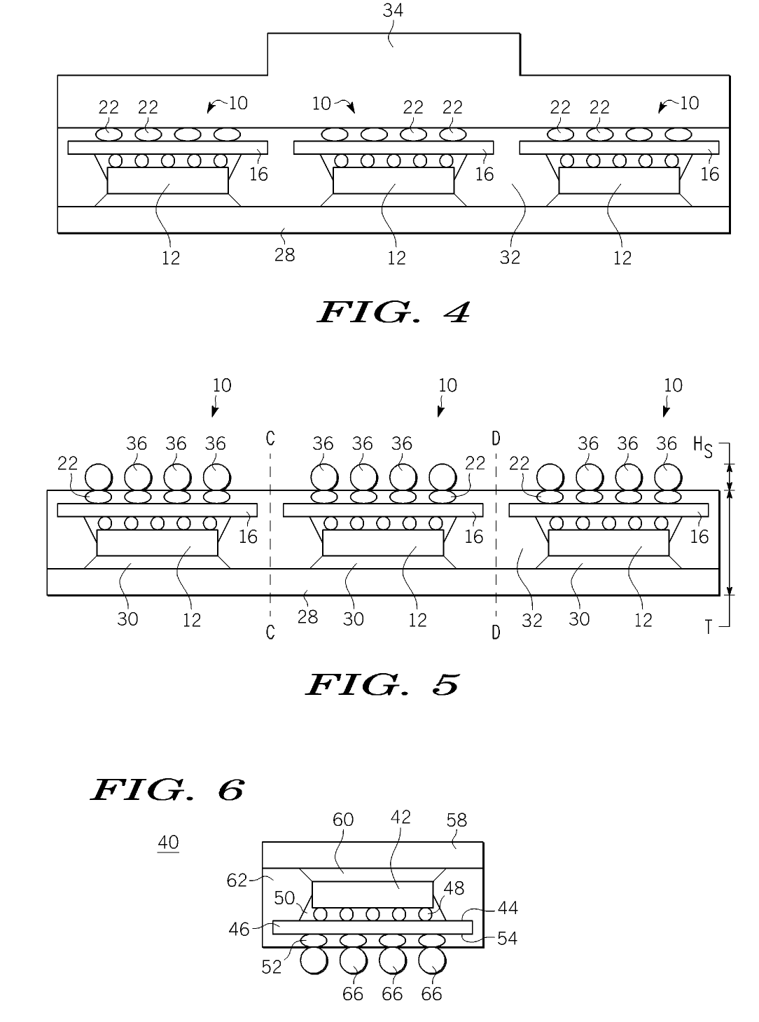

Referring now to FIG. 4, a molding operation is performed on the first level semiconductor packages 26 of FIG. 3. More particularly, the IC dice 12, the substrate 16, at least a portion of the interposer 28 (i.e., at least one side) and at least a portion of the first solder balls 22 are encapsulated with a molding compound 32. As shown in FIG. 4, the first solder balls 22 are compressed by a mold press 34 during the molding operation. Consequently, the encapsulated first level semiconductor packages 26 form a plurality of Land Grid Array (LGA) type second level semiconductor packages 10. Because the IC dice 12 and the substrate 16 are fully encapsulated, there are no exposed substrate surfaces or interfacial layers for the ingress of moisture from the ambient environment. Thus, the second level semiconductor packages 10 have reduced moisture sensitivity and are therefore less prone to moisture-induced failures. Further, because the molding compound 32 adheres strongly to the interposer 28, the second level semiconductor packages 10 are able to withstand the internal stresses exerted by the vaporised moisture and are therefore less susceptible to interfacial delamination or cracking. The molding operation is preferably a molded array process (MAP) in which multiple packages are formed by molding substantially simultaneously.

In this particular embodiment, the molding compound 32 has a moisture absorption rate of about 0.16 or less by weight percent (wt %). By encapsulating the first level semiconductor packages 26 in the molding compound 32 with a low moisture absorption rate, the moisture sensitivity of the second level semiconductor packages 10 is quite low.

The substrate 16 in this particular embodiment is cured before performing the molding operation, which reduces the moisture content in the second level semiconductor packages 10 as the curing process drives out moisture from the substrate 16. Additionally, the cured substrate 16 may be prebaked prior to performing the molding operation to ensure that the substrate 16 is substantially dry prior to encapsulation. After the molding operation, a post-mold curing process is preferably performed.

Referring now to FIG. 5, respective ones of a plurality of second conductive balls 36 are attached to respective ones of the compressed first conductive balls 22. The second conductive balls 36 are preferably controlled collapse chip carrier connection (C5) type solder balls and provide a standoff for the LGA type second level semiconductor packages 10. In this particular embodiment, the second conductive balls 36 have a height (Hs) of about 0.45 mm. However, it should be understood that the present invention is not limited by the height of the second solder balls 36.

A second singulating operation such as, for example, saw singulation, is performed along the vertical lines C-C and D-D to separate adjacent ones of the IC dice 12, thereby forming individual second level semiconductor packages 10. In this particular example, the second singulating operation is performed after the attachment of the second conductive balls 36 to the compressed first conductive balls 22. However, those of skill in the art will understand that the second singulating operation can also be performed before the attachment of the second conductive balls 36. In this particular embodiment, the second level semiconductor packages 10 have a thickness of about 1.3 mm. However, it will be understood that the present invention is not limited by the thickness of the second level semiconductor packages 10.

Although FIGS. 1 to 5 show only three (3) IC dice being attached, it will be understood that more or fewer IC dice 12 may be attached to the substrate 16, depending on the size of the substrate 16, the size of the IC dice 12, and the required functionality of the resulting semiconductor packages 10.

FIG. 6 is an enlarged cross-sectional view of a second level semiconductor package 10 formed in accordance with the procedure described above. The semiconductor package 40 includes an integrated circuit (IC) die 42 placed on and electrically connected to a first side 44 of a substrate 46. The IC die 42 is electrically coupled to the substrate 46 via a plurality of controlled collapse chip connection (C4) type interconnections 48. A gap between the IC die 42 and the substrate 46, surrounding the C4 type interconnections 48, is filled with an underfill material 50. A plurality of first solder balls 52 is attached to a second side 54 of the substrate 46. An interposer 58, in this particular example, a heat sink made of copper, is attached to the IC die 42 with an epoxy 60, such as a conductive epoxy, a non-conductive epoxy or a film epoxy. A molding compound 62 encapsulates the IC die 42, the substrate 46, at least a portion of the interposer 58 and at least a portion of the first solder balls 52. The molding compound 62 has a moisture absorption rate of about 0.16 or less by weight percent (wt %). Each of the first solder balls 52 has a compressed surface. Respective ones of a plurality of second solder balls 66 is attached to respective ones of the compressed first solder balls 52 to allow the second level semiconductor package 10 to be connected to other electrical components.

As is evident from the foregoing discussion, the present invention provides a semiconductor package with reduced moisture sensitivity and a method of making such a semiconductor package. In the present invention, a reduction in the moisture sensitivity of the semiconductor package is achieved by completely encapsulating a die and a substrate in a molding compound. To further reduce the moisture sensitivity of the semiconductor package, the die and the substrate are encapsulated in a molding compound with a low moisture absorption rate. Additionally, because the molding compound adheres strongly to an interposer to which the die is attached, the semiconductor package is capable of withstanding the internal stresses exerted by vaporised moisture. Consequently, the semiconductor package is less susceptible to moisture-induced package failure.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. For example, the die sizes and the dimensions of the steps may vary to accommodate the required package design. It is understood, therefore, that this invention is not limited to the particular embodiments disclosed, but covers modifications within the spirit and scope of the present invention as defined by the appended claims.

1. A method of making a semiconductor package, comprising:
placing an integrated circuit (IC) die on a first side of a substrate;
electrically coupling the IC die to the first side of the substrate;
attaching a plurality of first conductive balls to a second side of the substrate;
attaching an interposer to the IC die; and
performing a molding operation to encapsulate the IC die, the substrate, at least a portion of the interposer and at least a portion of the first conductive balls.

2. The method of making a semiconductor package of claim 1, further comprising curing the substrate before performing the molding operation.

3. The method of making a semiconductor package of claim 2, further comprising pre-baking the substrate before performing the molding operation.

4. The method of making a semiconductor package of claim 1, wherein a molding compound having a moisture absorption rate of about 0.16 or less by weight percent (wt %) is used to encapsulate the IC die, the substrate, the interposer and the first solder balls.

5. The method of making a semiconductor package of claim 1, wherein the interposer is a heat sink.

6. The method of making a semiconductor package of claim 5, wherein the heat sink is made of copper.

7. The method of making a semiconductor package of claim 5, wherein a conductive epoxy is used to attach the heat sink to the IC die.

8. The method of making a semiconductor package of claim 1, wherein the first conductive balls are compressed during the molding operation.

9. The method of making a semiconductor package of claim 8, further comprising attaching respective ones of a plurality of second conductive balls to respective ones of the compressed first conductive balls.

10. The method of making a semiconductor package of claim 9, wherein the first and second conductive balls comprise C5 solder balls.

11. The method of making a semiconductor package of claim 1, further comprising disposing an underfill material beneath the IC die after attaching the IC die to the substrate.

12. The method of making a semiconductor package of claim 11, wherein the IC die comprises a flip-chip die and the IC die is electrically coupled to the substrate with C4 solder balls.

13. A method of making a plurality of semiconductor packages, comprising:
placing a plurality of integrated circuit (IC) dice on a first side of a substrate;
electrically coupling the IC dice to the first side of the substrate;
attaching a plurality of first solder balls to a second side of the substrate;
attaching an interposer to the IC dice;
performing a molding operation to encapsulate the IC dice, the substrate, at least a portion of the interposer and at least a portion of the first conductive balls; and
performing a singulating operation to separate adjacent ones of the IC dice, thereby forming the plurality of semiconductor packages.

14. The method of making a plurality of semiconductor packages of claim 13, further comprising curing the substrate before performing the molding operation.

15. The method of making a plurality of semiconductor packages of claim 14, further comprising pre-baking the substrate before performing the molding operation.

16. The method of making a plurality of semiconductor packages of claim 13, wherein the IC die comprise flip-chip IC dice and the IC die are electrically coupled to the substrate with C4 solder balls.

17. The method of making a plurality of semiconductor packages of claim 16, further comprising disposing an underfill material beneath the IC die and around the C4 solder balls.

18. The method of making a plurality of semiconductor packages of claim 13, wherein the first conductive balls are compressed during the molding operation.

19. The method of making a plurality of semiconductor packages of claim 13, further comprising attaching respective ones of a plurality of second conductive balls to respective ones of the compressed first conductive balls.

20. A method of making a semiconductor package, comprising:
placing a flip-chip integrated circuit (IC) die on a first side of a substrate, wherein the flip-chip die includes a plurality of conductive bumps on a first side thereof that electrically couple the IC die to the substrate;
disposing an underfill material around the flip-chip die conductive bumps;
attaching a plurality of first conductive balls to a second side of the substrate, wherein the first conductive balls are electrically coupled to the flip-chip die by way of the substrate;
attaching a heat sink to a second side of the flip-chip die with a conductive epoxy material;
performing a molding operation to encapsulate the IC die, the substrate, at least a portion of the heat sink and at least a portion of the first conductive balls, wherein the first conductive balls are compressed and deformed by a mold press during the molding operation; and
attaching respective ones of a plurality of second conductive balls to respective ones of the compressed first conductive balls.
